(19) United States
(12) Patent Application Publication
(10) Pub. No.: US 2011/0034045 A1
(43) Pub. Date: Feb. 10, 2011

(54) Stacking Technique for Circuit Devices

(75) Inventors: Christoph Bilger, Munich (DE); Peter Gregorius, Munich (DE); Michael Bruennert, Munich (DE); Maurizio Skerlj, Munich (DE); Wolfgang Walthes, Munich (DE); Johannes Stecker, Munich (DE); Hermann Ruckerbauer, Moos (DE); Dirk Scheideler, Munich (DE); Roland Barth, Ottobrunn (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/536,854

(22) Filed: Aug. 6, 2009

(51) Int. Cl. H01R 12/00; H05K 1/00

(52) U.S. Cl. 439/83; 439/78

(57) ABSTRACT

Stackable circuit devices include mechanical and electrical connection elements that are optionally disengageable and disconnectable. The mechanical connection elements comprise pairs of complementary male and female plug-in engagement elements respectively arranged at opposite matching positions on top and bottom faces of each device package. The male and female plug-in engagement elements provide a mutual plug-in engagement. The electrical connection elements comprise a plurality of first and second complementary contact elements respectively arranged in opposite and matching positions on either the top or bottom face of each device package. When the circuit devices are stacked, the first contact elements are respectively configured to provide an electrical connection to a complementary matching second contact element of an adjacently plugged in circuit device. Some of the stackable circuit devices may accommodate an integrated memory die or chip and others of the stackable circuit devices may include line routing and distribution blocks.

### BACKGROUND

Today's integrated semiconductor circuit packages are usually soldered on a printed circuit board and connected two-dimensionally by wiring. In known multi-chip packages, the dice are for example bonded and connected by a substrate or connecting frame. Both known techniques define a fixed connectivity between the integrated semiconductor circuit packages and do not provide any possibility for the end user to change the connectivity.

Adding DIMMs (dual inline memory modules) is the only option currently available to increase the memory capacity of a computer in order to keep up with increasing computing capabilities of modern CPUs, memory controllers, and/or graphic controllers. Unfortunately, this solution creates a relatively large system and adds stubs that compromise signal integrity even when not used. Further, more memory space can be obtained in notebook computers by replacing existing SODIMMs (small outline dual inline memory module) with advanced SODIMMs having an increased memory space. This is an expensive solution, however, because the removed SODIMMs are no longer used and are eventually discarded.

A need exists for a stacking technique that permits three-dimensional connectivity between integrated circuit packages or the addition of supplemental integrated circuit packages or circuit modules by the end user even after assembly.

### SUMMARY

Stackable circuit device packages or circuit device frames are configured to accommodate an integrated semiconductor circuit die, chip, or package, e.g., a semiconductor memory die, chip, or package, and include mechanical and electrical connection elements so that the circuit device packages fit together as building blocks and can be stacked and snapped-in or plugged-in, thereby allowing stacking and combining of different circuit packages or adding and stacking of additional circuit packages of the same kind. Optionally, the mechanical connection is configured to provide a releasable connection so that the snap-in or plug-in can be assembled and disassembled by the end user.

### BRIEF DESCRIPTION OF THE DRAWINGS

FIG. 1A and FIG. 1B are schematic diagrams for explaining a first embodiment of stackable circuit devices.

FIGS. 2A, 2B, and 2C are schematic diagrams for explaining a second embodiment of stackable circuit devices.

FIGS. 3A, 3B, 3C, 3D, and 3E are schematic diagrams for explaining a third embodiment of stackable circuit devices.

FIGS. 4A, 4B, 4C, 4D, and 4E are schematic diagrams for explaining a fourth embodiment of a stackable circuit device.

FIGS. 5A, 5B, 5C, and 5D are schematic diagrams for explaining different kinds of electrical connection elements which can be used in the stackable circuit devices of the embodiments.

FIG. 6 shows a schematic diagram for explaining chip-select connectivity in stackable circuit devices in the first embodiment depicted in FIGS. 1A and 1B.

FIGS. 7A and 7B are schematic diagrams for explaining a fifth embodiment of stackable circuit devices.

FIGS. 8A and 8B are schematic diagrams for explaining a sixth embodiment of stackable circuit devices.

### DETAILED DESCRIPTION

Embodiments of stackable circuit devices will be described in detail below with reference to the accompanying drawings. In the drawings it is noted that identical reference numerals are used to designate identical or similar elements throughout the several views and that elements are not necessarily shown to scale. Further it is to be understood that throughout the present specification directional terminology such as “top,” “bottom,” “left,” and “right” is not used restrictively but simply chosen for purposes of easier description. In this regard, directional terminology such as “top,” “bottom,” etc. is used with reference to the orientation of components being described in the figures. Because components of the embodiments of the present invention can be positioned in a number of different orientations, the directional terminology is used for purposes of illustration and is in no way limiting.

The following description describes in a general sense a stacking technique for circuit devices using circuit packages that contain electrical and mechanical connection elements and that fit together as building blocks and can be “snapped in” or “plugged in” and electrically connected together by matching electrical connection elements and thereby allows combining of different circuit devices in optional numbers or adding additional circuit devices. The mechanical connection is done in a way that the “snap-in” or “plug-in” can be assembled and optionally also disassembled by the end user. In this regard the terminology “snap-in” or “plug-in” are used as synonymous expressions describing a mechanical snap-in or plug-in engagement of stacked circuit devices. The snap-in or plug-in engagement can provide a predetermined force forcing together every two snapped-in or plugged-in circuit devices of a stack of such circuit devices. The amount of this force is sufficient to urge together the electrical contact elements of stacked circuit devices. Further, preferably, the electrical connection is achieved by electrical connection elements which can be connected in matching positions, and optionally are disconnectable by a user.

Even if the following description of the embodiments is by way of example describing the use of memory circuit devices and memory modules as the stackable circuit devices, one skilled in the art will readily understand from the following description that the embodiments are not restricted to stackable integrated semiconductor memory devices or stackable memory modules but also encompasses other kinds of circuit devices such as field programmable circuit devices, programmable gate array circuit devices, micro switch arrays, etc.

### First Embodiment

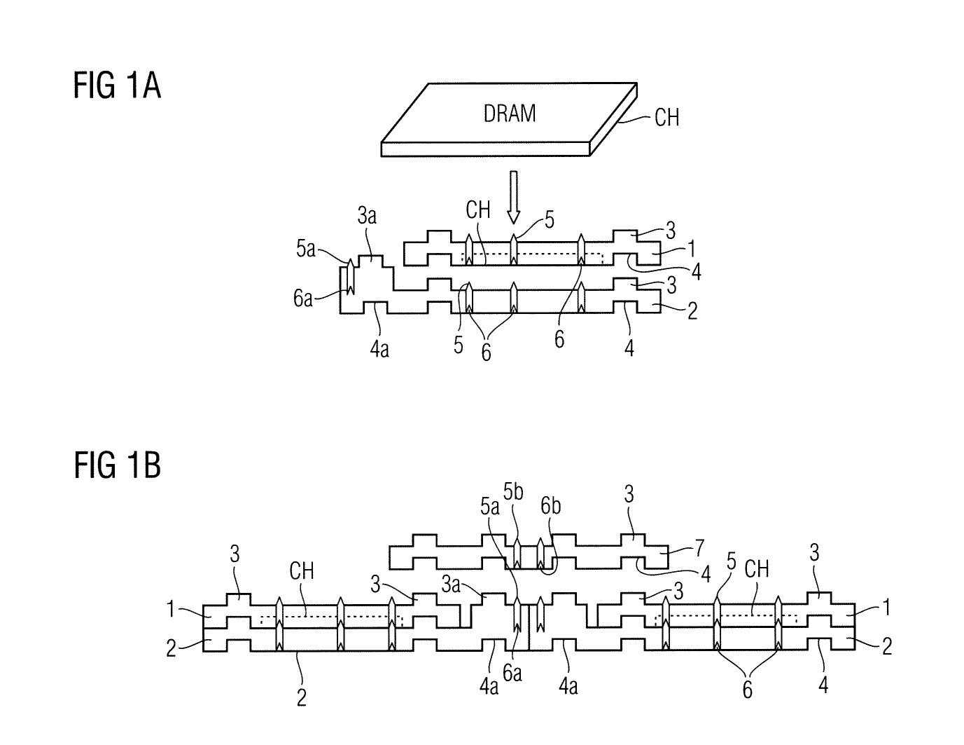

FIGS. 1A and 1B schematically show a first embodiment of stackable circuit devices. A first stackable and pluggable circuit device 1 configured to accommodate an integrated semiconductor circuit die or chip includes mechanical connection elements 3, 4 and electrical connection elements 5, 6. The semiconductor circuit die or chip is in the present embodiment exemplified as a DRAM chip CH.

Further, a second stackable and pluggable circuit device 2 is configured as a routing building block configured for routing signal and power supply lines from an underlying substrate, for example a printed circuit board (not shown), such as a printed circuit board for DIMMs to corresponding electrical connection elements of the first circuit device 1. The second circuit device 2 like the first circuit device 1 includes mechanical and electrical connection elements 3, 4 and 5, 6, respectively.

The mechanical connection elements 3, 4 comprise at least one pair of male 3 and complementary female 4 plug-in engagement elements respectively arranged at opposite positions on a top face and a bottom face of the device package of the first circuit device 1. The male and female plug-in engagement elements 3, 4 are configured in complementary pairs to provide a mutual plug-in or snap-in engagement of male plug-in engagement elements 3 into mating female plug-in engagement elements 4. That is, each complementary pair of male and female plug-in engagement element of the first circuit device 1 and the second circuit device 2 is respectively arranged at matching opposite positions on the top face and the bottom face, respectively, of the first circuit device 1 and the second circuit device 2. For example the pluggable device package of the first circuit device 1 may comprise four pairs of complementary male and female plug-in engagement elements 3, 4 and the pluggable device package of the second circuit device 2 may also comprise four pairs of complementary male and female plug-in engagement elements 3, 4 arranged at positions matching with the four pairs of male and female plug-in elements of the pluggable device package of the first circuit device 1. In this way the first circuit device 1 can be stacked upon the second circuit device 2 wherein the male plug-in engagement elements 3 on the top face of the device package of the second circuit device 2 are plugged in or snapped into the female plug-in engagement element 4 on the bottom face of the device package of the first circuit device 1, thereby resulting in a stacked arrangement of the first circuit device 1 upon the second circuit device 2 as it is depicted in the lower part of FIG. 1B.

Further, in this embodiment, the second circuit device 2 includes at least one pair of complementary second male and female plug-in engagement elements 3a and 4a provided at a thickened left region of the pluggable device package of the second circuit device 2. While the first circuit device 1 is stackable on top of the second circuit device 2 upon engagement of their male plug-in engagement elements 3 into their female plug-in engagement element 4, the second circuit device 2 is stackable on a surface of for example a printed circuit board (not shown) which may be provided with male plug-in engagement elements which can be plugged in the female plug-in engagement elements 4, 4a on the bottom face of the second circuit device 2. The present invention however is not restricted of stacking the second (lower) circuit device 2 on a printed circuit board. In the same manner the second circuit device 2 can be stacked upon another circuit device which for example may be a memory controller package, a package of a CPU, etc. in the same manner.

As depicted in FIGS. 1A and 1B, the stackable circuit devices 1, 2 of the first embodiment include the electrical contact elements 5, 6 arranged to electrically connect device package-external signal and power supply lines (in the embodiment, the signal and power supply lines are provided in the routing building block implemented by the second circuit device 2) to corresponding signal and power supply connections of the DRAM chip CH accommodated within the device package of the first circuit device 1. The electrical contact elements 5, 6 comprise a plurality of first contact elements 5 arranged in a predetermined arrangement on the top faces of each the first circuit device 1 and the second circuit device 2 and a plurality of complementary second contact elements 6 which respectively correspond to and are configured to be connected with the first contact elements 5 and are respectively arranged in the identical arrangement as the first contact elements at the bottom faces of each opposite device package of the first circuit device 1 and the second circuit device 2. Each first contact element 5 is respectively configured to provide an electrical connection to a complementary matching second contact element of an opposite mating plugged-in further circuit device.

In a state depicted in FIG. 1B where two first circuit devices 1 are stacked upon two second circuit devices 2, the second electrical contact elements 6 on the bottom face of the device packages of the first circuit devices 1 are configured to provide a firm and secure electrical connection to the complementary first electrical contact elements 5 provided on the top face of the device packages of the second circuit devices 2.

The second device package 2 further includes at its left side region (in the FIG. 1A), where the at least one pair of second male and female plug-in engagement elements 3a, 4a are provided, additional first and second electrical contact elements 5a, 6a, the function of which is now explained with reference to FIG. 1B. The shown configuration of the stacked first and second circuit devices 1 and 2 provides the option of stacking a third circuit device 7 on top of the two laterally adjoining stacked first and second circuit devices 1 and 2. Namely, this third stackable circuit device 7 also includes pairs of complementary male and female plug-in engagement elements 3, 4 and pairs of complementary first contact elements 5b and second contact elements 6b respectively arranged in matching portions on the top face and bottom face of the third circuit device 7 so that the latter can be stacked on the top face of the two adjoining stacks of first and second circuit devices 1 and 2. This structure is achieved by plugging the respective male plug-in engagement element 3 on the top face of the first circuit devices 1 and the second male plug-in engagement elements 3a on the top face of the second circuit devices 2 matingly into the complementary female plug-in engagement elements 4 on the bottom face of the third circuit device 7. This plugging action achieves an electrical connection of the first contact elements 5a on the top face of the adjoining second circuit devices 2 with the complementary mating second electrical contact elements 6b on the bottom face of the third circuit device 7. As shown in FIG. 1B the third circuit device 7 also includes at its top face the first electrical contact element 5b and the male plug-in engagement element 3 so that it provides the possibility of stacking a fourth stackable circuit device (not shown) on top of the third circuit device 7.

To achieve the arrangement depicted in FIG. 1B where the third circuit device 7 is stackable on the top of an arrangement of two adjacent stacks of first and second circuit devices 1 and 2, the second circuit device 2 includes the thickened region at one of its end faces (depicted as the leftmost region in FIG. 1A) so that the level of the top face including the second male plug-in engagement elements 3a and the additional first contact element 5a is raised upon the level of the top face of the remaining part of the second circuit device 2. That is, as shown in FIG. 1B the top faces of the first circuit devices 1 and of the top faces of the adjoining thickened end regions of the two adjacent second circuit devices 2 respectively have an equal level. In the first embodiment of the stackable circuit devices 1, 2, the matching complementary first and second electrical contact elements 5, 6, 5a, 6a, 5b, 6b have respectively identical positions on the top and bottom faces of the device packages of each of the first, second and third circuit devices 1, 2 and 7. Further, each pair of the male and female plug-in engagement elements 3, 4, 3a, 4a have equal size and are formed in complementary shape integrally with the device packages of each of the circuit devices 1, 2, and 7. Further, the paired male and female plug-in engagement elements 3, 4 of the device package of the first circuit device 1 and the corresponding paired male and female plug-in engagement elements 3, 4 of the device package of the second circuit device 2 are formed in peripheral regions, for example in edge regions of the device packages of the first and second circuit devices 1, 2 and outside a central region of the first circuit device 1, the central region being configured for accommodating the DRAM chip CH.

At least a part of the complementary male and female plug-in engagement elements 3, 4 and 3a, 4a of the first, second, and third circuit devices 1, 2, and 7 additionally may have the function of electrical connection elements, for example to supply power potentials to the integrated semiconductor circuit device, chips, or packages, CH accommodated in the respective device packages.

Further, optionally the complementary male and female plug-in engagement elements 3, 4 and 3a, 4a may be formed to be mutually disengagable for example by applying a disengaging force between two adjacently plugged-in or strapped-in device packages.

Further, while all the male plug-in engagement elements 3, 3a and all the female plug-in engagement elements 4, 4a are respectively shown to have the same size, optionally it can be advantageous to provide pairs of complementary male and female plug-in engagement elements having smaller size and at least one pair of complementary male and female plug-in engagement element with increased size as compared with the pairs of smaller male and female plug-in engagement elements.

Further, optionally the complementary first and second contact elements 5, 6 of the first circuit device 1 might be arranged within the central region of the device package, and the first and second contact elements of the second circuit device 2 can be likewise arranged in this central region in identical positions as the first and second contact elements 5, 6 of the first circuit device 1. In the first circuit device 1, according to the first embodiment, the first and second electrical contact elements 5, 6 are preferably mutually connected together by through-silicon connectors or wires (not shown) leading through the accommodated DRAM chip CH from an upper main face to a lower main face thereof. In the second circuit device 2 and the third circuit device 7, the first and second electrical contact elements 5, 6, 5a, 6a, 5b, 6b can be mutually connected together in a point-to-point fashion by connecting lines (not shown) leading through the device package of the second and third circuit devices 2, 7 from their top face to their bottom face, respectively.

While the above description describes the first and second electrical contact elements 5, 6, 5a, 6a, 5b, 6b of the first, second, and third circuit devices 1, 2, and 7 to provide a firm mutual electrical contact upon the plug-in or snap-in action of two adjacently stacked circuit devices, optionally, it can be advantageous to configure the first and second electrical contact elements of at least two adjacently stacked and plugged-in circuit devices to be disconnectable, in particular in case the pairs of male and female plug-in engagement elements of these two circuit devices are provided to be mutually disengagable.

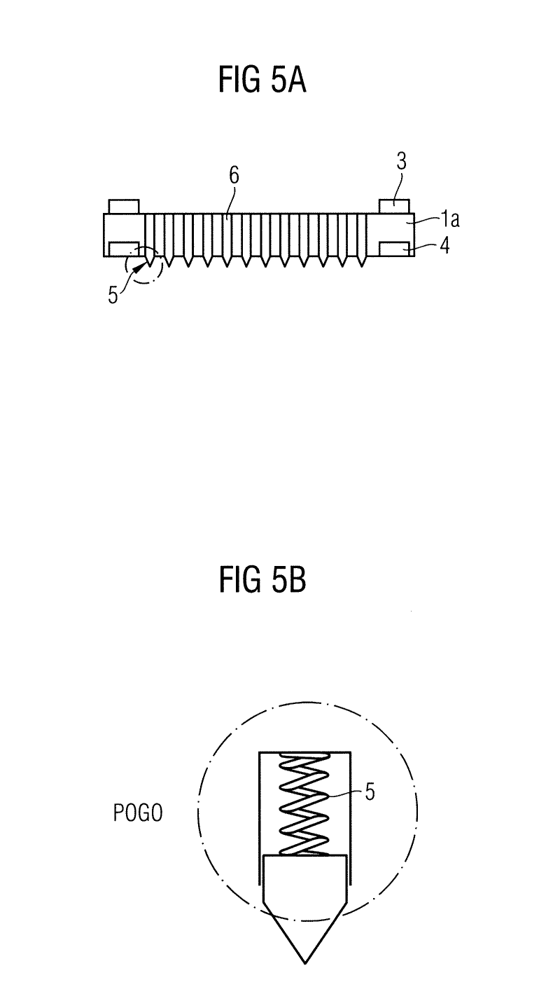

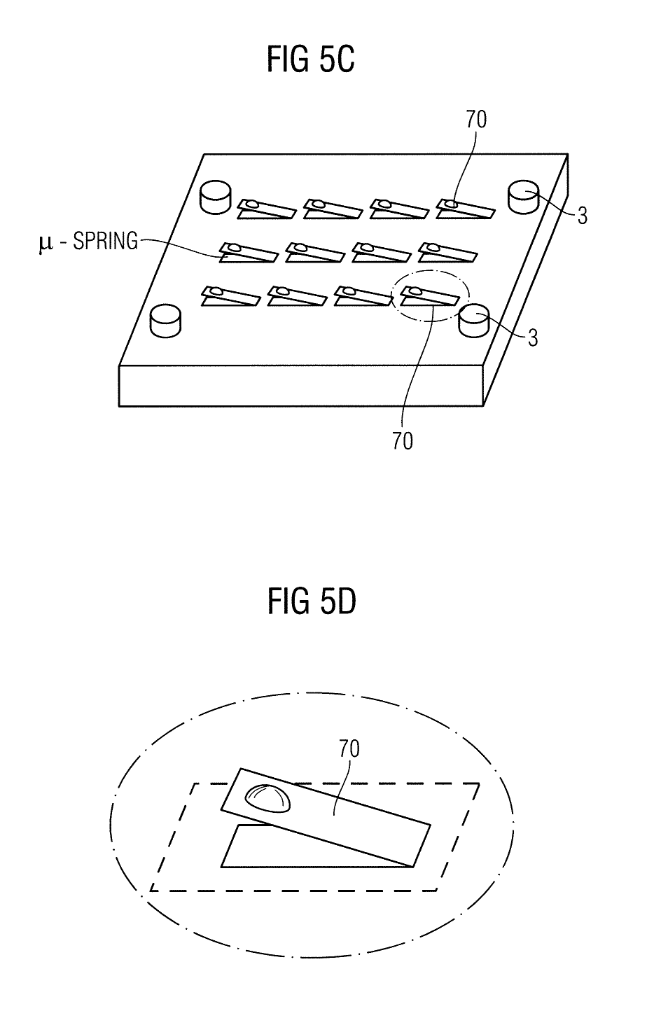

In accordance with a first implementation, the first or second electrical contact element 5, 6, 5a, 6a, 5b, 6b of the first, second and third circuit devices 1, 2 and 7 may be formed as micro spring contacts, and the complementary ones of the first and second electrical contact elements 5, 6, 5a, 6a, 5b, 6b may be configured as micro spring-receiving contacts respectively mating with a corresponding micro spring contact (FIGS. 5C, 5D).

According to an alternative implementation, the first or second electrical contact elements 5, 6, 5a, 6a, 5b, 6b of the first, second, and third circuit devices 1, 2, and 7 can be configured as pogopin contacts, and the complementary ones of the first and second electrical contact elements 5, 6, 5a, 6a, 5b, 6b may be configured as pogopin-receiving contact pads or lands respectively mating with a corresponding pogopin contact.

According to a further implementation, the first and second electrical contact elements 5, 6, 5a, 6a, 5b, 6b of the first, second, and third circuit devices 1, 2, and 7 may respectively be configured as micro-bumps and micro-bump receiving contact pads or lands to be electrically contact-connected together by a predetermined pressure force exerted upon plug-in engagement of mating male and female plug-in engagement elements of the stacked circuit devices.

The foregoing description of the first embodiment referring to FIGS. 1A and 1B describes the device package of the first circuit device 1 configured to accommodate a DRAM chip or die CH, wherein the DRAM chip or die CH is fixedly mounted and accommodated in a device package of the first circuit device 1 and, as it is known in the art, encapsulated by an isolating material. However, one skilled in the art will readily grasp from the foregoing description that the first embodiment is not restricted to the accommodation of a DRAM chip or die CH within the device package of the first circuit device 1 and that other integrated semiconductor circuit chips or dice such as gate arrays, programmable gate arrays, etc. may be accommodated in the device package of the first circuit device 1. Moreover the skilled person will easily notice from the foregoing description that the first embodiment of the invention is not restricted to stacking of only a first circuit device 1 upon a second circuit device 2 configured as a routing building block and that the first embodiment allows stacking and plugging in a plurality of first circuit devices 1 which, for example, accommodate a DRAM chip CH and that it is also possible to stack a plurality of first circuit devices 1 on the third circuit device 7 in case the latter is also configured as a routing building block similar to the second circuit device 2.

As described above with reference to FIGS. 1A and 1B the first embodiment of the present invention uses device packages that contain electrical and mechanical connection elements that are the complementary first and second contact elements 5, 6, 5a, 6a, 5b, 6b and the pairs of male and female plug-in engagement elements 3, 4, 3a, 4a. These device packages are fitted together as building blocks and can be plugged in or snapped in, thereby allowing different ICs to be combine or additional ICs to be added. The mechanical connections and the electrical contacts are realized in a manner that the stackable circuit devices can be assembled and optionally the stack thereof can be disassembled by the end user.

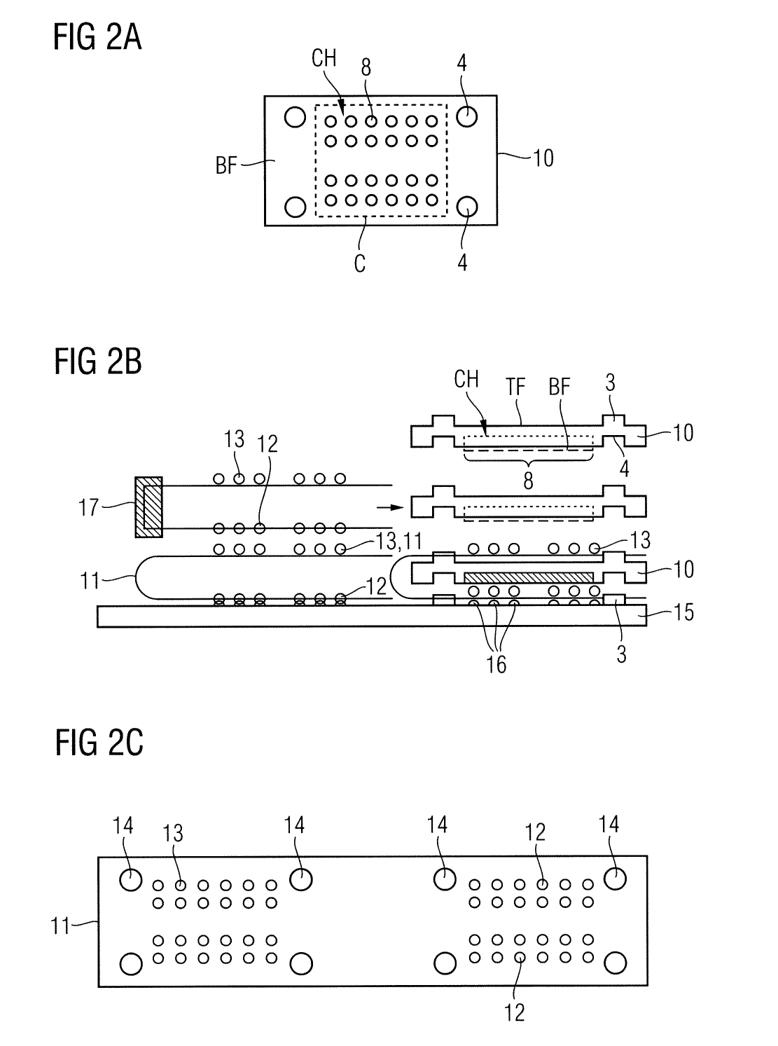

While the first embodiment of the present invention described above with reference to FIGS. 1A and 1B includes the plurality of complementary first and second contact elements respectively arranged on the top and bottom faces of the stackable device packages and each second contact element are configured and adapted to make a connection with the complementary first contact element of an adjacent matingly plugged-in circuit device wherein that connection optionally can be disconnectable, the description of a second embodiment of the present invention which will be described below with reference to FIGS. 2A, 2B, 2C, and 2D provides another kind of a stackable circuit device 10 which comprises a plurality of only one kind of electrical contact elements 8 on a bottom face BF of the device package of the stackable circuit device 10 and an additional contact substrate 11.

### Second Embodiment

FIG. 2A shows a bottom view of the stackable circuit device 10 according to the second embodiment. Similar to the stackable circuit device 1 of the first embodiment, the stackable circuit device 10 is also configured to accommodate an integrated semiconductor circuit die or chip, e.g. a DRAM chip CH in a central region C of the device package. This central region C is surrounded in FIG. 2A by a broken line and the bottom face BF of the device package of the stackable circuit device 10 comprises within the central region C a predetermined arrangement of a plurality of electrical contact elements 8 preferably each of the same kind.

As shown in FIGS. 2A and 2B, the device package of the stackable circuit device further comprises, similar to the device packages 1, 2 of the first embodiment, in a peripheral region outside the central region C, pairs of male and female plug-in engagement elements integrally formed with the device package on the top face TF and the bottom face BF, respectively, in particular in an edge region of the device package to provide a mutual plug-in engagement of male plug-in engagement elements 3 into mating female plug-in engagement elements 4 in a state where a plurality of the circuit devices 10 are stacked one upon another.

The contact substrate 11 depicted in FIGS. 2B, 2C and magnified in FIG. 2D includes an arrangement of a plurality of first electrical substrate contact elements 12 and a corresponding and mirror-symmetrical arrangement of the same plurality of second electrical substrate contact elements 13, each plurality of first and second substrate contact elements 12, 13 having identical predetermined arrangement as the arrangement of the electrical contact elements 8 on the bottom face BF of the device package of the circuit device 10. Each individual first substrate contact element 12 is connected to a corresponding one of the second substrate contact elements 13 by one of a plurality of electrical connection lines (not shown) that are mutually insulated and routed within the contact substrate 11. As shown in FIG. 2B, each electrical substrate contact element of the first and second substrate contact elements 12, 13 may be implemented as a micro-bump contact while the contact elements 8 on the bottom face BF of the device package of the stackable circuit device 10 may be arranged as micro-bump-receiving pads in the predetermined arrangement. Further, the contact substrate 11 includes an arrangement of a plurality of through-holes 14 which are arranged at predetermined positions that match with the positions of the male and female plug-in engagement elements 3, 4 of the device package of the circuit device 10 in the arrangement shown in FIG. 2B.

In the contact substrate 11 according to its unfold state shown in FIG. 2C, the arrangement of the first substrate contact elements 12 is provided at a first end region, and the arrangement of the second substrate contact elements 13 is provided spaced apart from the arrangement of the first substrate contact elements 12 at an opposite second end region in the length direction of the contact substrate 11. The contact substrate 11 may be more or less rigid, or according to an optional implementation, the contact substrate 11 is formed as a flexible contact foil, and the substrate connection lines are formed as flexible connection lines.

The form, flexibility, size, and length of the contact substrate 11 are respectively determined so that, in a state where the first electrical substrate contact elements 12 are in matching positions with the electrical contact elements 8 on the bottom face BF of the device package of the stackable circuit device 10 and the flexible contact foil 11 is bent around an end face of the device package (according to FIG. 2B the left end face thereof) so that the second end portion of the flexible contact foil 11 is arranged in parallel to the top face TF of the circuit device 10, the second substrate contact elements 13 come into matching registration with the positions of the first substrate contact elements 12 and the electrical contact elements 8 on the bottom face BF of the device package of the circuit device 10.

In this position the contact substrate 11, e.g., the flexible contact foil 11 has the function of transferring and routing the electrical contact elements 8 on the bottom face BF of the device package to identical positions on the top face TF of the device package of the circuit device 10 to provide a mutual electrical contact from each of the electrical contact elements 8 on the bottom face of the device package with respectively corresponding contact electrical elements 8 on the bottom face BF of a further mating device package upon plug-in engagement of the male plug-in engagement element on the top face of an underlying circuit device 10 and female plug-in engagement elements on the bottom face of a further circuit device stacked upon the underlying circuit device 10 in a state where a plurality of circuit devices 10 are stacked one upon another in matching positions. In this state, the male plug-in engagement elements 3 penetrate through the holes 14 in the flexible contact foil 11. Thereby, these holes 14 serve as position adjustment elements of the contact substrate, e.g. of the flexible contact foil 11. FIG. 2B further shows a stiffening and supporting element 17 assisting for assembling the contact substrate 11 to the circuit devices 10. As it is clearly depicted in FIG. 2B, a plurality of circuit devices 10 can be stacked one upon another by inserting the contact-transferring contact substrate 11. A lowermost circuit device 10 may be fixedly or releasably mounted on a motherboard 15 in the same manner previously described, wherein the motherboard 15 may include mating male plug-in engagement elements 3 and micro-bumps or micro-bump receiving pads 16.

The above descriptions of the first and second embodiments of the stackable circuit devices enable the skilled person to understand that the stackable circuit devices 10 can also be stacked upon a first and/or second and/or third stackable circuit device 1, 2, and 7 if matching complementary electrical contact elements are provided such as micro-bump contacts and corresponding pads.

The foregoing descriptions of the first and second embodiments describe that device packages of the circuit devices 1 and 10 are configured to accommodate an integrated semiconductor memory chip CH or die, for example a DRAM chip CH. Therefore, each circuit device 1 and 10 can be implemented as a semiconductor memory device, wherein the semiconductor memory circuit chip CH or die, in particular, the DRAM chip CH is accommodated in the central region C of a respective device package.

Using these stackable semiconductor memory devices and the further circuit devices/elements of the first or second embodiment, a three-dimensional semiconductor memory module can be constructed, which comprises at least one stack of a plurality of the semiconductor memory devices being stacked one upon another and each semiconductor memory device accommodating at least one semiconductor memory chip or die, e.g., a DRAM chip CH.

The stackable circuit devices according to the first and second embodiment comprise pluggable device packages configured to accommodate an integrated semiconductor circuit die or chip, e.g., a DRAM chip CH encapsulated within a specialized stackable device package.

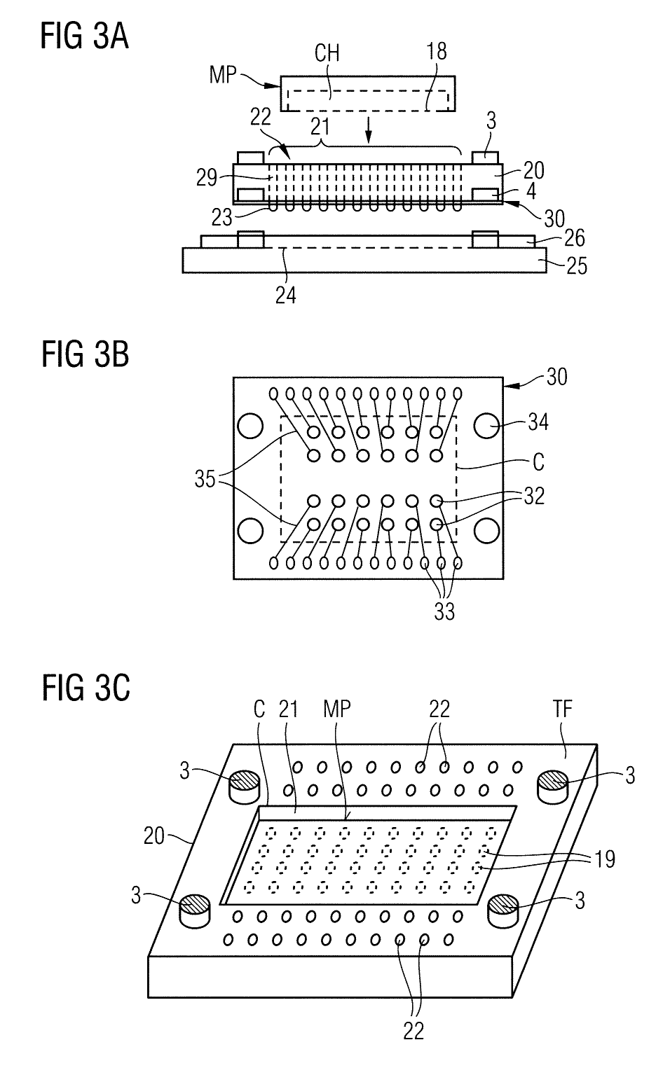

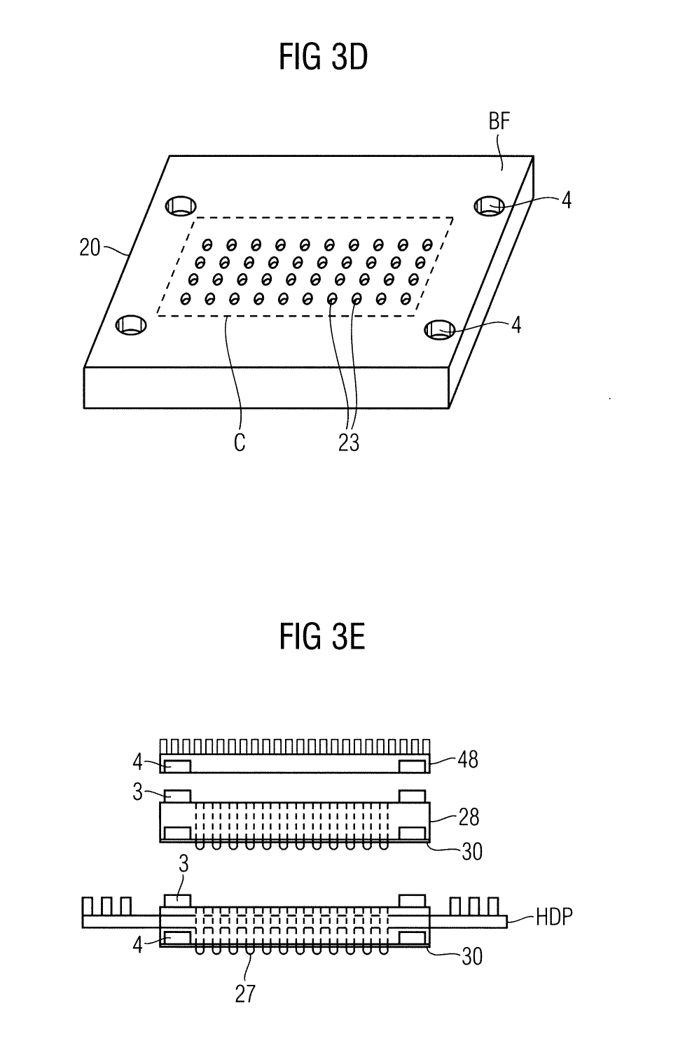

FIGS. 3A, 3B, 3C, 3D, and 3E schematically show a third embodiment of stackable circuit devices which is a solution for standard integrated semiconductor circuit packages, e.g., standard DRAM chip packages. As shown in FIGS. 3A and 3C, a memory chip package MP which, for example, includes a DRAM chip CH, can be accommodated within a central cut-out 21 formed in a central region C of a first device frame 20 (FIG. 3C). The memory chip package MP, which includes, e.g., a DRAM chip or die CH, comprises a predetermined arrangement of electrical memory package contacts 18 at its bottom face. The device frame 20 comprises within the central cut-out 21 electrical frame contacts 19 in identical arrangement and positions as the DRAM contacts 18 so that the DRAM contacts 18 are contact-connected with matching frame contacts 19 within the central cut-out 21 of the device frame 20. FIG. 3C shows a perspective view of a top face TF of the device frame 20 accommodating a DRAM memory package MP within the central cut-out 21, wherein the DRAM contacts 18 are individually contact-connected with the frame contacts 19 indicated by small circles in broken lines.

FIG. 3C further shows first electrical contact elements 22 arranged on the top face TF of the device frame 20 at peripheral regions thereof. Within the device frame 20, the first electrical contact element 22 are at least partly and individually connected:

a) to respectively corresponding ones of the frame contacts 19 and thereby to corresponding one of the DRAM contacts 18; and

b) to second electrical contact elements 23 arranged on the bottom face BF of the device frame 20 as depicted in FIG. 3D.

The second electrical contact elements 23 at the bottom face BF of the device frame 20 are arranged within the central region C defining the cut-out 21. According to FIGS. 3A, 3B, and 3E, the third embodiment of the stackable circuit device further comprises a contact distribution substrate 30. The contact distribution substrate 30 includes a plurality of first substrate contact elements 32 arranged within a central region C of the contact distribution substrate 30 in identical positions, number, and arrangement as the positions, number, and arrangement of the second electrical frame contact elements 23 at the bottom face BF of the device frame 20. The contact distribution substrate 30 further includes a plurality of second substrate contact elements 33 arranged in a peripheral region of the contact distribution substrate 30 in identical positions, number, and arrangement as the positions, number, and arrangement of the first electrical frame contact elements 22 on the top face TF of the device frame 20. Electrical connection lines 35 formed within the contact distribution substrate 30 are insulated from one another and connect, in a point-to-point fashion, individually at least a part of the first substrate contact elements 32 to respectively corresponding ones of the second substrate contact elements 33. The contact distribution substrate 30 is, according to an optional implementation, formed as an elastic foil, and the first and second substrate contact elements 32, 33 are formed as micro-bumps, respectively.

As shown in FIGS. 3A and 3E, the contact distribution substrate 30 is placed in operation on the bottom face of each device frame 20, 27, 28, and the micro-bumps of the first substrate contact elements 32 are contact-connected with the second electrical frame contact elements 23 on the bottom face BF of the device frames 20, 27, and 28. Therefore, in a state where plural device frames forming circuit building blocks are stacked one upon another, the contact distribution substrate 30 distributes electrical signal and supply power potential to supply contacts provided by the second frame contact elements 23 on the bottom face of an upper device frame 20, 28 being stacked upon and plugged in an underlying device frame 20, 25, 27 via the first substrate contact elements 32, the second substrate contact elements 33 and the connection lines 35 to the first frame contact element 22 provided on the top face TF of the respective underlying device frame 20, 25, 27. Further, in a case where an undermost device frame 20 is stacked on and electrically connected with contacts 24 of a printed circuit board, e.g., a motherboard 25 which has a motherboard mounting frame 26, the contact distribution substrate 30 arranged between the bottom face of the device frame 20 and the motherboard 25 serves to distribute the frame contacts 23 on the bottom face BF of the device frame 20 to motherboard contacts 24 having identical number, positions, and arrangement as the second substrate contact elements 33 of the contact distribution substrate 30. In similar fashion as in the first and second embodiments described above, the device frames 20, 27, and 28 have pairs of male and complementary female plug-in engagement elements 3, 4 respectively arranged on the top face TF and the bottom face BF of the device frames 20, 27, 28. These pairs of male and female plug-in engagement elements 3, 4 may optionally be configured to be disengagable if once mutually plugged in and are arranged at peripheral edge regions of the device frames 20, 27, 28 outside the region where the electrical frame contact elements 22, 23 are formed. Further, optionally the matching electrical contact elements may be configured to be electrically disconnectable.

Further, the contact distribution substrate 30 as shown in FIG. 3B includes through-holes or cut-outs 34 provided in the contact distribution substrate 30 in peripheral positions matching with the positions of the pairs of male and female plug-in engagement elements 3, 4 of the device frames 20, 27 and 28.

The third embodiment of the stackable circuit devices described above, similar to that of the first and second embodiments, also allows the end user to create three-dimensional connectivity between integrated semiconductor circuit devices or adding additional integrated semiconductor circuits, e.g., DRAM device frames accommodating normal DRAM memory chip size packages MP. The skilled person will readily derive from the above description that a plurality of circuit devices, for example the device frames 20 including the memory chip package MP, can be stacked one upon another by merely plugging the male plug-in engagement element 3 into the complementary female plug-in engagement element 4 wherein the contact distribution substrate 30 serves to distribute the second electrical contact element 23 on the bottom face BF of device frame 20 in a point-to-point fashion to corresponding second electrical contact elements 22 on the top face TF of an underlying circuit device, for example comprising a further device frame 20 including a standard DRAM memory package MP.

In case a plurality of circuit devices such as the device frames 20, including the standard memory packages MP, are stacked one upon another, generation of heat may raise a problem in operation.

Therefore, the third embodiment may optionally comprises a stackable device frame 27 including a heat dissipation pipe HDP thereby forming a heat dissipation pipe building block as shown in FIG. 3E.

According to the third embodiment, the device frame 27 can be inserted between every two stacked device frames at any position requiring heat dissipation from the stack.

Further, according to the third embodiment, FIG. 3E shows that the stackable circuit devices may comprise a further device frame 28 forming a mechanical fixing and cover building block and further a heat spreader 48 forming a topmost circuit device of the stack of circuit devices according to the third embodiment of the invention.

The first to third embodiments of the present invention described above with reference to FIGS. 1 to 3 are directed to stackable circuit devices wherein an integrated semiconductor circuit die, chip, or package is accommodated within a pluggable device package or pluggable device frame. That is, single device packages or frames are stackable one upon another to allow the creation of new three-dimensional connectivity between integrated semiconductor circuits or individually adding and plugging in further stackable integrated semiconductor circuit devices, for example integrated semiconductor memory circuit devices even after assembly by the end user.

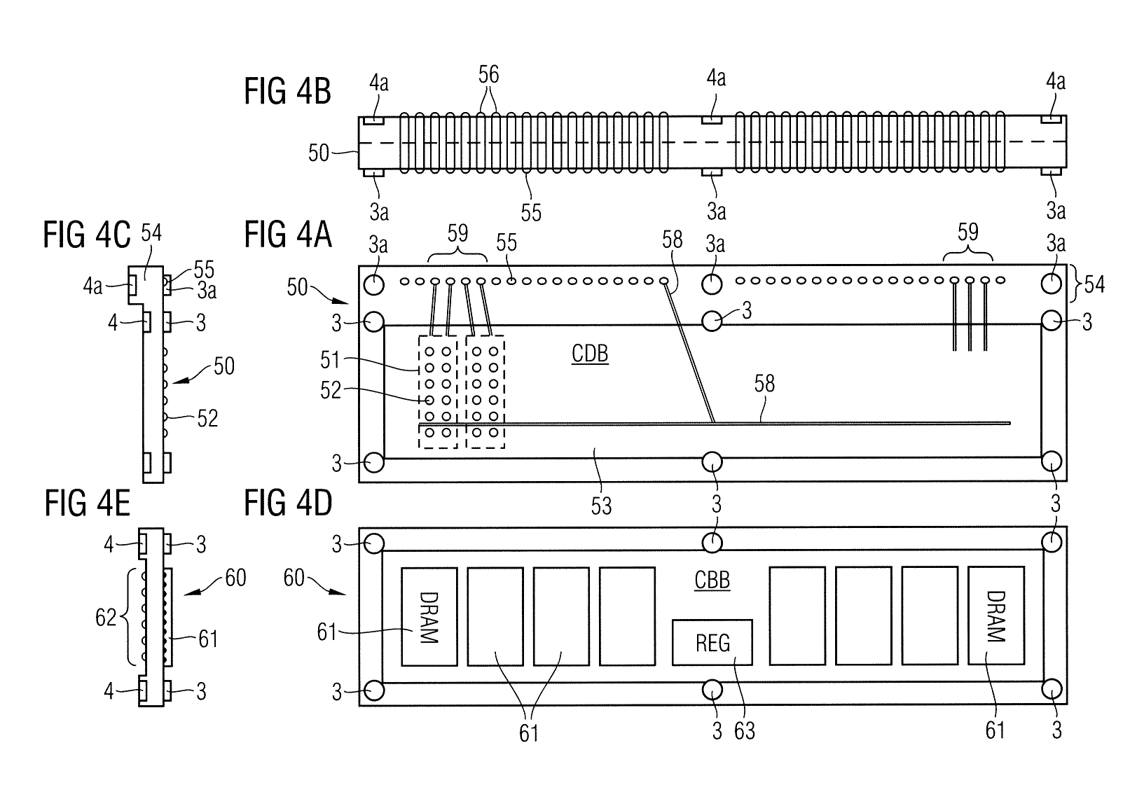

The following description of the fourth embodiment of the present invention referring to FIGS. 4A, 4B, 4C, 4D, and 4E describes stackable circuit devices which comprise a combination of a stackable circuit building block (in the following abbreviated as CBB) and a stackable line routing and contact distribution block (in the following abbreviated as CDB). The CBB is stackable and pluggable on the CDB, and a plurality of CDBs can be stacked one upon another.

A plan view of the top face of the CBB depicted in FIG. 4D and a side view of an edge side of the CBB depicted in FIG. 4E show that the CBB comprises a device substrate or a frame 60 forming a printed circuit board which may have a similar configuration as a known DIMM. On its top face the device frame 60 comprises an arrangement of a plurality of integrated semiconductor circuit packages 61, of a first type, e.g., DRAM circuit packages 61 and one integrated semiconductor circuit package 63 of another type, e.g. comprising a register circuit 63. The semiconductor circuit packages 61, 63 can be soldered on the top face of the device frame 60 of the CBB, and the signal and power supply contacts on the bottom faces of the semiconductor circuit packages 61, 63 are connected through the printed circuit board of the device frame 60 to corresponding plural electrical frame contact elements 62 arranged on the bottom face of the device frame 60 of the CBB as it is shown in FIG. 4E. These electrical frame contact elements 62 can be respectively grouped in association with each semiconductor device package 61 and 63, and each electrical frame contact element of a respective group is connected to a corresponding package contact of the associated integrated semiconductor device package 61, 63, wherein the electrical frame contact elements 62 are configured to provide an electrical connection of signal and power supply lines from the CDB to each of the semiconductor device packages 61, 63 via a plurality of corresponding second electrical contact elements 52 arranged on the top face of the stackable line routing and contact distribution block CDB.

The CDB comprises a line routing and contact distribution substrate, e.g., a printed circuit board 50 including a mounting region 53 provided in a predetermined and approximately central region on the top face of the printed circuit board 50, wherein the second electrical contact elements 52 are arranged in this mounting region 53 and grouped in groups 51 in association to the groups of the frame contact elements 62 of the CBB. In other words, the electrical frame contact elements 62 of the CBB are respectively arranged in matching positions with the second electrical contact elements 52 of the CDB and are configured to provide an electrical connection of the respective signal and power supply lines from the semiconductor device packages 61, 63 of the CBB to the associated second electrical contact elements 52 within the central mounting region 53 of the CDB.

The CDB further comprises a plurality of pairs of third and fourth electrical contact elements 55 and 56 as shown in FIGS. 4A and 4B. These pairs are at least partly individually connected together, and the third and fourth electrical contact elements 55, 56 are respectively arranged on the top face and the bottom face of the CDB at a first edge side 54 of the substrate/printed circuit board 50 and spaced apart from the central mounting region 53 which includes the second electrical contact element 52. As shown in the FIGS. 4A, 4B, the pairs of third and fourth electrical contact elements 55, 56 may respectively be arranged in a straight line immediately opposite to one another in matching positions on the top face and the bottom face of the substrate/printed circuit board 50 of the CDB. Further, each pair of the third and fourth electrical contact elements 55 and 56 is connected to an associated second electrical contact element 52 by corresponding electrical distribution lines 58, 59 routed and isolated within the substrate/printed circuit board 50 of the CDB. For example the electrical distribution lines 58 form a command/address bus and the electrical distribution lines 59 form a data bus DQ. It is to be understood that, for the sake of a simplified representation of the distribution lines 58, 59, FIG. 4A depicts only an exemplifying part of electrical distribution lines 59 and also only a part of the second electrical contact elements 52.

As shown in FIGS. 4D and 4E, the device frame 60 of the circuit building block CBB further comprises a plurality of first pairs of male and complementary female plug-in engagement elements 3, 4 respectively arranged at matching opposite positions at edge sides of the device frame 60 of the CBB. The first pairs of male and female plug-in engagement elements 3, 4 are configured to provide a mutual plug-in engagement of male plug-in engagement elements into mating female plug-in engagement elements.

In a configuration where the fourth embodiment of the stackable circuit device forms a stack comprising a plurality of CBBs, each individually stacked upon an associated CDB, each male plug-in engagement element 3 of the CBB is plugged in or snapped in a mating complementary female plug-in engagement element 4 provided on the bottom face of an overlying CDB. To stack and plug the CBB on an underlying CDB and one CDB upon another CDB, the CDB comprises a plurality of second pairs of male and female plug-in engagement elements 3, 4 which are respectively arranged in matching positions on the top face and the bottom face of the substrate/printed circuit boards 50 of the CDB and in the matching positions and equal number as the first pairs of male and female plug-in engagement elements 3, 4 of the CBB.

Further, the substrate/printed circuit board 50 of the CDB also includes a plurality of third pairs of male and female plug-in engagement elements 3a, 4a respectively provided on the top face and the bottom face on the same first edge side 54 of the CDB which comprises the pairs of third and fourth electrical contact elements 55 and 56. The third pairs of male and female plug-in engagement elements 3a, 4a may, for example, by formed in approximately a straight line with the third and fourth electrical contact elements 55, 56.

As shown in FIG. 4C, the first edge side 54 of the substrate/printed circuit board 50, which includes the pairs of the third and fourth electrical contact elements 55 and 56 and includes the third pairs of male and female plug-in engagement elements 3a, 4a, has a region of an increased thickness of the substrate/printed circuit board 50, wherein the remaining area of the substrate/printed circuit board 50 is formed comparatively thinner.

Having this structure, the substrate/printed circuit board 50 of the CDB is configured so that one CBB plugged-in and stacked upon the mounting region of the CDB is accommodated between every two CDBs stacked upon one another.

An alternative solution to accommodate a CBB between two CDBs stacked one upon another is to provide a thinned area in the central mounting region 53 in the top face of the substrate/printed circuit board 50 of the CDB, the thinned area having a larger edge size and a slightly increased depth compared with the edge size and thickness of the CBB carrying the device packages 61, 63 on its top face. The last mentioned alternative solution having the thinned area in the mounting region 53 is not shown in the drawing.

Like the first to third embodiments, the fourth embodiment as described above and depicted in FIGS. 4A-4E uses packages, i.e., circuit building blocks CBBs and line routing and contact distribution blocks CDBs that fit together and can be plugged in or snapped in and thereby allow the creation of new three-dimensional connectivity between integrated circuit boards/modules, e.g., memory modules or adding additional integrated circuit boards/modules, e.g., memory modules by the end user even after assembly.

As it is described above in relation to the first to third embodiments of the invention, each male and female plug-in engagement element 3 formed on the top face of the printed circuit board 50 of the CDB and each mating female plug-in engagement element 4 formed on the bottom face of the printed circuit board 60 of the CBB may be configured to provide upon the plug-in engagement of mating male and female plug-in elements, a predetermined contact force urging together the frame contact elements on the bottom face of the CBB with the second contact elements on the top face of the CDB. Further each male plug-in element 3 on the top face of the printed circuit board 60 of the CBB and each third male plug-in engagement element 3a on the top face of the CDB if plugged in a mating female plug-in engagement element 4′, 4a on the bottom face of an overlying CDB in a state where a plurality of CDBs each carrying one plugged-in CBB are stacked one upon another may provide a predetermined contact force urging together the third electrical contact elements 55 on the top face of an underlying CDB and the fourth electrical contact elements 56 of a further CDB stacked upon the underlying CDB. Similar to the male and female plug-in engagement elements of the first to third embodiments, those of the fourth embodiment optionally can be configured to provide a releasable plug-in engagement. Further at least a part of these male and female plug-in engagement elements can optionally also have an electrical connection function.

Principally first contact elements and complementary second contact elements can be respectively realized as disconnectable contact elements and can be configured as micro-bumps and complementary micro-bump receiving pads.

FIGS. 5A and 5B show an alternative pluggable circuit device 1a where first electrical contact elements 5 are implemented as pogopin contacts and respectively complementary second electrical contact elements 6 are configured as complementary pogopin receiving contact pads or lands mating with the corresponding pogopin contacts 5.

Alternatively, FIGS. 5C and 5D schematically depict a further alternative pluggable circuit device 1b wherein first or second electrical contact elements 70 are implemented as micro-spring contacts wherein the complementary second or first electrical contact elements (not shown) are configured as micro-spring receiving contacts mating with the corresponding micro-spring contact.

Like the first or second electrical contact elements of the fourth embodiment, also the third or fourth electrical contact elements of the fourth embodiment may be configured as pogopin contacts 5 and the respective complementary of the third and fourth electrical contact elements may be configured as pogopin receiving contact pads or lands mating with the corresponding pogopin contacts as schematically depicted in FIGS. 5A and 5B. Alternatively, the third or fourth electrical contact elements of the fourth embodiment may be configured as micro-spring contacts 70 and the complementary fourth or third electrical contact elements may be configured as micro-spring receiving contacts (not shown) mating with the corresponding micro-spring contacts as schematically depicted in FIGS. 5C and D.

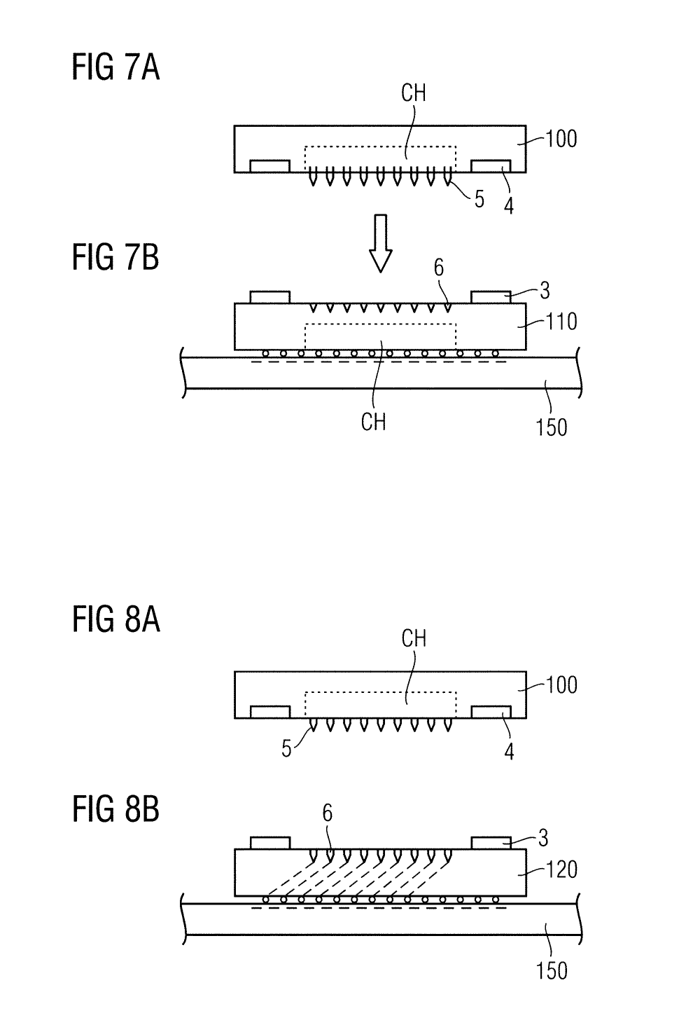

FIGS. 7A and 7B schematically show a fifth embodiment of stackable circuit devices including a first circuit device 110 accommodating an integrated semiconductor circuit die or chip, e.g., a semiconductor memory die or chip CH. The first circuit device 110 is fixedly mounted on and connected to an underlying substrate/printed circuit board 150, for example by soldering solder bumps provided on the bottom side of the first circuit device 110 on corresponding soldering pads provided on the top face of the substrate 150 (FIG. 7B).

Further a second circuit device 100 shown in FIG. 7A also accommodates an integrated semiconductor circuit die or chip, e.g., a semiconductor memory die or chip CH and can be stacked on and plugged-in the top face of the first circuit device 110. This is achieved by arranging mechanical and electrical connection elements on both the top face of the first circuit device 110 and the bottom face of the second circuit device 100, respectively. The mechanical connection elements include male plug-in engagement elements 3 and matching complementary female plug-in engagement elements 4 provided at matching positions on either the top face of the first circuit device 110 or the bottom face of the second circuit device 100. According to FIGS. 7A and 7B, the male plug-in engagement elements 3 are arranged on the top face of the first circuit device 110 and the female plug-in engagement elements 4 are arranged on the bottom face of the second circuit device 100. The electrical connection elements comprise complementary first and second contact elements 5, 6 respectively arranged in matching positions on either the top face of the first circuit device 110 or on the bottom face of the second circuit device 100. When stacking the second circuit device 100 on the first circuit device 110, the male plug-in engagement elements 3 are plugged into the female plug-in engagement element 4 and the first electrical contact element 5 are contact-connected with the second electrical contact elements 6. Similar to the male and female plug-in engagement element of the first to fourth embodiments, the plug-in engagement elements of the fifth embodiment can be configured to allow disengagement thereof. At least a part thereof can be configured to provide an electrical connection function. Further, the first and second electrical contact elements 5, 6 of the fifth embodiment can be configured as or disconnectable contact element.

The skilled person will readily grasp from the above description of the fifth embodiment that it allows stacking only one additional second circuit device 100, e.g., a memory device, on top of an underlying first circuit device 110, e.g., a memory device too.

The sixth embodiment depicted in FIGS. 8A and 8B also allows stacking of one second circuit device 100 on top of a first circuit device 120 fixedly connected by soldering to an underlying substrate/printed circuit board 150. Also, this sixth embodiment comprises complementary first and second electrical contact elements 5, 6 respectively provided in respectively matching positions either on the top face of the first circuit device 120 or on the bottom face of the second circuit device 100 and complementary male and female plug-in engagement elements 3, 4 respectively provided on either the top face of the first circuit device 120 or on the bottom face of the second circuit device 100 in respectively matching positions.

While in the fifth embodiment depicted in FIGS. 7A and 7B both circuit devices 110 and 100 are configured to accommodate an integrated semiconductor chip or die, for example a DRAM chip or die, in the sixth embodiment depicted in FIGS. 8A and 8B, only the second circuit device 100 is configured to accommodate an integrated semiconductor chip or die, for example a DRAM chip or die CH. The first circuit device 120 is configured as a line routing and contact distribution device.

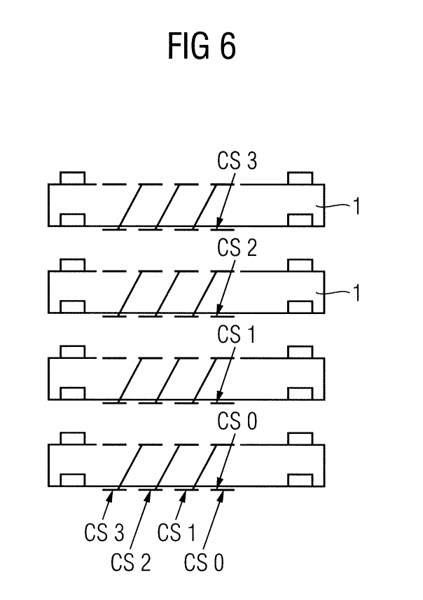

A further embodiment of the present invention is schematically depicted in FIG. 6 where a plurality of stackable circuit devices, for example circuit devices 1 according to FIGS. 1A and 1B each comprising a DRAM chip or die (not shown) are pluggable and stackable one upon another. Chip select signals CS0, CS1, CS2, CS3 for selecting each one of the plurality of DRAM chips accommodated in the circuit devices 1 are respectively laterally shifted so that each device package of the circuit devices 1 can receive its own chip select signal always at the same electrical contact element on the bottom face thereof.

The foregoing descriptions describe stacking techniques for (optionally releasable) stackable circuit devices which allow creation of a new three-dimensional connectivity between integrated semiconductor circuit devices, in particular integrated semiconductor memory devices or adding additional integrated semiconductor circuit devices, e.g., integrated semiconductor memory devices by the end user even after assembly.

Generally, it is proposed to use device packages that fit together as building blocks and contain connectable and (optionally and disconnectable) electrical and mechanical connection means so that in a state where a plurality of device packages are stacked one upon another these device packages can be plugged in or snapped in. The snap-in or plug-in connection is accomplished in a manner that the stackable circuit devices can be assembled and optionally disassembled by the end user.

Having studied the foregoing description, the skilled person will readily understand that the different embodiments allow to construct very small subsystems, e.g., by placing a memory circuit device or a stack of memory circuit devices directly above a memory controller. Further, the embodiments enable the end user to configure the system according to his wishes. Further, the end user is enabled to change the system by assembling and optionally disassembling differently. This allows an easy repair process if a single device fails. The end user further advantageously can extend the memory density or capacity of a memory system. Some embodiments of the present invention allow that the same DRAM chips can be used as for conventional chip packages. Just solder-balls need to be assembled.

The embodiments of the invention have, in particular, following effects:

they allow a very small sub-system (for example placing memory device packages directly above the memory controller);

they enable the end user to configure a memory system according to his wishes;

they enable the end user to change the systems connectivity by assembling differently;

they allow an easy repair process if a single device package fails;

they allow the end user to extend the memory density or capacity of a memory system;

they allow use of the same DRAMs used for conventional device packages (just solder-balls need to be assembled); and

they allow the creation of three-dimensional integrated semiconductor circuit systems.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A circuit device, comprising:
a pluggable device package configured to accommodate an integrated semiconductor circuit die, chip, or package and including mechanical and electrical connection elements, wherein:
the mechanical connection elements comprise at least one pair of complementary male and female plug-in engagement elements respectively arranged at opposite positions on a top and a bottom face, respectively, of the device package and configured to provide a mutual plug-in engagement of male plug-in engagement elements into mating female plug-in engagement elements;
the electrical connection elements are arranged to electrically connect device package-external signal and power supply lines to corresponding signal and power supply connections of the semiconductor circuit die, chip, or package if accommodated within the device package; and
the electrical connection elements comprise a plurality of at least first contact elements arranged in a predetermined arrangement either on the top face or the bottom face of the device package, and each of the first contact elements is respectively configured to provide an electrical connection to a complementary mating opposite contact element of an adjacent matingly plugged-in circuit device in a state where a plurality of the circuit devices are stacked one upon another.

2. The circuit device as claimed in claim 1, further comprising a plurality of second contact elements respectively corresponding to each of the first contact elements and being arranged at the respective opposite face of the top and bottom face, and wherein each second contact element is electrically connected within the device package to a corresponding one of the first contact elements and configured to make an electrical connection with a complementary first contact element of an adjacent matingly plugged-in circuit device in a state where a plurality of the circuit devices is stacked one upon another.

3. The circuit device as claimed in claim 2, wherein the device package is configured as a device frame having in its top face a central cut-out configured to accommodate as the integrated semiconductor circuit at least one electronic circuit component.

4. The circuit device as claimed in claim 3, wherein the first and second electrical contact elements are mutually interconnected by through-silicon vias leading through the accommodated semiconductor circuit chip or die from an upper main face to a lower main face thereof.

5. The circuit device as claimed in claim 3, wherein one kind of the first or second electrical contact elements is arranged on the top face of the device frame at peripheral regions thereof, different from the peripheral regions of the device frame forming the male and female plug-in engagement elements, and the respective other kind of the second or first electrical contact elements of the device frame are arranged on the bottom face at a central region of the device frame, wherein the central region is configured to accommodate at least one electronic circuit component.

6. The circuit device as claimed in claim 5, further comprising a contact distribution substrate including:
a plurality of first electrical substrate contact elements respectively insulated from one another and arranged in a central region of the contact distribution substrate in corresponding arrangement as the arrangement of the electrical contact elements at the bottom of the device frame;
a plurality of second electrical substrate contact elements respectively insulated from one another and arranged in a peripheral region of the contact distribution substrate in corresponding arrangement as the arrangement of the electrical contact elements at the top face of the device frame; and
electrical substrate distribution lines respectively insulated from one another and routed within the contact distribution substrate in a point-to-point fashion from at least a part of the first electrical substrate contact element to corresponding ones of the second electrical contact elements.

7. The circuit device as claimed in claim 6, wherein the contact distribution substrate is arranged between each opposite and top face of adjacent device frames in a state where plural device frames are stacked one upon another and between a bottom face of a device frame and a motherboard in a state where the device frame is mounted on the motherboard wherein signals and power supply are distributed through the first and second substrate contact elements and the substrate distribution lines, the circuit device additionally comprising a heat removal pipe, and wherein the contact distribution substrate comprises an elastic material, the electrical contact elements at the top face and the bottom face of the device frame and the first and second electrical substrate contact elements being respectively configured as micro bumps.

8. The circuit device as claimed in claim 1, further comprising:
a contact substrate configured as a flexible contact foil and including a plurality of first electrical substrate contact elements and a same plurality of second electrical substrate contact elements, the first and second substrate contact elements being arranged in the predetermined arrangement and respective first substrate contact elements being connected to corresponding second substrate contact elements via respective connection lines mutually insulated and routed within the contact substrate, wherein:
the arrangement of the first substrate contact elements is provided in a first end region in a length direction of the contact substrate, and the arrangement of second substrate contact elements is provided spaced apart from the arrangement of the first substrate contact elements in a second end region of the contact substrate in the length direction thereof opposite to the first end region thereof; and
in a state where the contact substrate is arranged or bent around an edge of the pluggable device package and the first substrate contact elements are arranged in parallel to the second substrate contact elements, the positions of the second substrate contact elements are in registration with the respective positions of the first substrate contact elements and with the respective positions of the contact elements of the device package to provide a mutual electrical contact from each of the first contact elements of the device package with respectively corresponding contact elements of another mating device package upon engagement of male and female plug-in engagement elements in a state where a plurality of mating device packages are stacked one upon another.

9. The circuit device as claimed in claim 1, wherein each pair of male and female plug-in engagement elements is respectively arranged at peripheral regions on the top and bottom face of the device package and outside a central region thereof provided for accommodating the semiconductor circuit die, chip, or package.

10. The circuit device as claimed in claim 1, wherein peripheral regions of the top and bottom face of the device package outside a central region thereof have increased thickness as compared with a thickness of the central region of the device package.

11. The circuit device as claimed in claim 1, wherein each pair of the male and female plug-in engagement elements is configured to provide, upon plug-in engagement of mating male and female plug-in elements, a predetermined contact force urging together the first and second contact elements of two stacked device packages.

12. A circuit device, comprising:
a combination of a circuit building block (CBB) and a stackable line routing and contact distribution block (CDB), the CBB being stackable and pluggable on the CDB and comprising:
a device frame including a top face and a bottom face and a plurality of integrated semiconductor circuit device packages arranged on either the top face or the bottom face and complementary mechanical connection elements and electrical connection elements, wherein the complementary mechanical connection elements of the CBB comprise:
a plurality of first pairs of complementary male and female plug-in engagement elements, either of the male or female plug-in engagement elements of the first pairs respectively arranged at matching opposite positions on the top and bottom face of the device frame and configured to provide a mutual plug-in engagement of male plug-in engagement elements into mating female plug-in engagement elements, and wherein
the electrical connection elements comprise a plurality of first electrical contact elements arranged on the bottom face of the device frame in predetermined positions and grouped in positional association with each device package, the first electrical contact elements of a respective group being respectively connected to a corresponding package contact of an associated circuit device package, and the first electrical contact elements being configured to provide an electrical connection of signal and power supply lines from the CDB to each of the circuit device packages on the CBB.

13. The circuit device as claimed in claim 12, wherein the CDB includes pairs of complementary mechanical connection elements, electrical connection elements and electrical distribution lines,
the mechanical connection elements of the CDB comprising a plurality of second and third pairs of male and female plug-in engagement elements,
either the male or the female plug-in engagement elements of the second pairs being respectively arranged at the top face and the bottom face of the CDB at respectively matching opposite positions and having the same number as the first pairs of male and female plug-in engagement elements of the CBB and respective positions matching with the first pairs of male and female plug-in engagement elements of the CBB, and
the electrical connection elements of the CDB comprising a plurality of complementary second electrical contact elements arranged on the top face of the CDB in a position thereof in association to and matching arrangement with each of the first electrical contact elements of the CBB so that each of the second electrical contact elements of the CDB is contact-connectable to the first electrical contact elements of the CBB in a state where the CBB is stacked and plugged-in on the top face of the CDB and where either the first male plug-in engagement elements or the first female plug-in engagement elements of the CBB are in plugged-in engagement with the corresponding mating second female or male plug-in engagement element of the CDB.

14. The circuit device as claimed in claim 13, wherein the CDB further comprises:
a plurality of pairs of third and fourth electrical contact elements respectively arranged on the top face and the bottom face of the CDB along an edge side thereof and spaced apart from a region of the CDB which includes the second electrical contact elements, and each paired third and fourth electrical contact element being respectively and separately connected together and further connected to a corresponding one of the second electrical contact elements through corresponding electrical distribution lines routed within the CDB.

15. The circuit device as claimed in claim 14, wherein:
the third pairs of male and female plug-in engagement elements of the CDB are arranged along the same edge side thereof as the pairs of third and fourth electrical contact elements;
the CDB comprises a printed circuit board; and
a region at a first edge side of the CDB where the third pairs of male and female plug-in engagement elements are arranged has an increased thickness as compared with the thickness of the remaining area of the printed circuit board of the CDB.

16. The circuit device as claimed in claim 14, wherein the CDB comprises a printed circuit board and comprises a thinned area in the top face and in the central region thereof, the thinned area having slightly greater edge size and an increased depth as respectively compared with the edge size and thickness of the CBB.

17. The circuit device as claimed in claim 14, wherein each pair of the male and female plug-in engagement elements is configured to provide, upon plug-in engagement of mating male and female plug-in elements, a predetermined contact force urging together the first electrical contact elements of the CBB and the second electrical contact elements of the CDB in a state where the CBB is stacked upon and plugged in the CDB.

18. A memory device comprising:
a pluggable first device package accommodating an integrated semiconductor memory die or chip and including mechanical and electrical connection elements, wherein:
the mechanical connection elements comprise a plurality of at least first male or first female plug-in engagement elements at predetermined positions on a bottom face of the first device package and are configured to provide a mutual corresponding plug-in engagement of the male plug-in elements of the first device package into a plurality of mating female plug-in engagement elements of a second device package or a mutual plug-in engagement of the first female plug-in engagement elements of the first device package into a corresponding plurality of male plug-in engagement elements of the second device package positioned in matching arrangement beneath the bottom face of the pluggable first device package; and
the electrical connection elements are arranged to electrically connect signal lines and power supply lines from the second device package with corresponding signal connections and power supply connections of the semiconductor memory die or chip accommodated within the first device package and comprise a plurality of at least first electrical contact elements arranged in a predetermined arrangement on the bottom face of the first device package and each first electrical contact element being respectively configured to provide an electrical connection to a corresponding matching electrical contact element of the second device package in a state where the pluggable first device package is plugged in and stacked upon the underlying second device package.

19. The memory device as claimed in claim 18, wherein:
the first device package further comprises on its top face of the first device package a plurality of second male or female plug-in engagement elements, wherein the second male plug-in engagement elements are provided in the event the first plug-in engagement elements are female plug-in engagement elements, and the second female plug-in engagement elements are provided in the event the first plug-in engagement elements are male plug-in engagement elements, the plurality of second plug-in engagement elements being provided in a number corresponding to the first plug-in engagement elements, each second plug-in engagement elements being arranged in predetermined positions matching respective positions of the first plug-in engagement elements,
the memory device further comprising a plurality of second electrical contact elements respectively complementary to the first electrical contact elements and arranged on the top face of the first device package, and wherein each second electrical contact element is configured to make an electrical connection with a corresponding one of a plurality of first electrical contact elements of another overlying and matchingly plugged-in device package of the same type as the first memory device package in a state where a plurality of the memory device packages are stacked one upon another.

20. The memory device as claimed in claim 18, wherein the second device package comprises a semiconductor memory die or chip of the same type as the first semiconductor memory die or chip and is fixedly soldered on a printed circuit board, and the second device package comprises on its top face matching plug-in engagement elements and matching electrical contact elements.
